(19) United States
(12) Patent Application Publication
(10) Pub. No.: US 2007/0054503 A1
(43) Pub. Date: Mar. 8, 2007

(54) Film forming method and fabrication process of semiconductor device

(75) Inventors: Hiroyuki Takaba, Nirasaki-Shi (JP); Toshihide Nabatame, Tokyo (JP); Masaru Kadoshima, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-ku (JP); Renesas Technology Corp., Chiyoda-ku (JP)

(21) Appl. No.: 11/510,679

(22) Filed: Aug. 28, 2006

(30) Foreign Application Priority Data
Sep. 5, 2005 (JP) 2005-256947

(51) Int. Cl. H01L 21/31; H01L 21/469

(52) U.S. Cl. 438/785

(57) ABSTRACT

A method of forming a film on a substrate includes a first step of carrying out first film formation on an insulation layer formed on the substrate by an ALD process, and a second step of carrying out second film formation in continuation to the first step by a CVD process.

### BACKGROUND OF THE INVENTION

The present invention generally relates to semiconductor devices and more particularly to a film forming method for forming a film on a substrate and a fabrication process of semiconductor device that uses such a film forming method.

A CVD (chemical vapor deposition) process is used extensively for fabrication of electronic components including semiconductor devices and display devices. By using a CVD process, it becomes possible to achieve excellent step coverage far superior to the case of forming a film by using a sputtering process.

In the technology of CVD, it is possible to form various films by using various source gases. Particularly, it is possible to form a metal film or metal nitride film on a substrate by a so-called MOCVD (metal-organic CVD) process that uses a metal organic source.

Meanwhile, with recent advancement of high-performance semiconductor devices, there is an increasing demand for further improved quality and uniformity for the films formed by a CVD process. In relation to such a demand, an ALD (atomic layer deposition) process draws attention these days in view of its capability of providing excellent film quality and excellent uniformity with regard to the film thickness and film quality. There are semiconductor devices that use a film formed with such an ALD process according to the needs.

Patent Reference 1 Japanese Laid-Open Patent Application 2004-235482 official gazette

Patent Reference 2 Japanese Laid-O-pen Patent Application 2003-109914 official gazette

### SUMMARY OF THE INVENTION

As noted previously, there have been cases in which the quality of the film does not satisfy the required standard in the case the film formation is carried out by a CVD process. For example, there have been cases in which a film formed by an MOCVD process fails to provide the uniformity needed for semiconductor devices in terms of film thickness and film quality.

For example, in the case of forming a metal film on a substrate by an MOCVD process that uses a metal organic source, the film formation tends to start from the metal nuclei formed on the substrate by a nucleation process.

On the other hand, there are cases, in MOCVD process, in which the density of nucleation becomes small and there are formed small number of nuclei, depending on the metal organic source used. In such a case, growth of nuclei formed with such low density tends to become predominant in the film formation process as compared with the nucleation itself, and there can be caused problems such as low film density or formation of voids in the film.

FIG. 1 shows the case of forming a gate electrode of a MOS transistor, which is an exemplary semiconductor device, by forming a metal film on a gate insulation film 2 by using an MOCVD process so as to cover a substrate 1.

In the case of forming a metal film on such a gate insulation film 2 by an MOCVD process, there is a problem that the nuclei, which serves for the starting point of film growth, are formed sparsely with low probability, and hence with low density. On the other hand, there are cases in which film formation (growth of nuclei) occurs suddenly when there is caused nucleation. In such a case, there is caused sudden growth in the metal film.

When this occurs, there can be a situation shown in FIG. 1 in which there are regions on the gate insulation film 2 not covered with the gate electrode (metal film 3) because of too large diameter of the crystals constituting the metal film. Further, there can be a situation in which the metal film 3 contains void. Thereby, the semiconductor device that uses the metal film 3 that contains defects therein suffers from the problem of poor electric performance such as too large leakage current.

In the case of forming such a metal film while using an ALD process, on the other hand, there arises a problem, in view of small growth rate characteristic to an ALD process, in that the efficiency of semiconductor device production is deteriorated in spite of the fact that the film quality or uniformity of film quality and film thickness is improved because of the small crystal diameter achieved with such an ALD process.

FIG. 2 shows the relationship between the deposition time and film thickness for formation of a metal film for the case of using an ALD process and for the case of using an (MO)CVD process.

Referring to FIG. 2, it can be seen that there appears an incubation time in which there occurs no substantial film growth when a CVD process is used, in view of the fact that nucleation does not take place for some time after starting the film growth in such a CVD process. On the other hand, it can be seen that there occurs sharp increase of film growth rate once there is caused nucleation and the film formation starts to proceed. Thereby, there is formed a thick film.

In the case of an ALD process, on the other hand, there appears no incubation time contrary to a CVD process, and film growth (nucleation) occurs steadily immediately after start of the film formation. On the other hand, it can be seen that the growth rate is small with the ALD process, and the productivity of device formation is deteriorated seriously as compared with the case of using a CVD process.

Now, Patent Reference 1 (Japanese Laid-Open Patent Application 2004-235482) discloses a film forming method that combines a CVD process and an ALD process. On the other hand, the technology of Reference 1 uses the dimple morphology of metal film formed by a CVD process so as to include therein crystals of large diameters, for the purpose of increasing the capacitance of a capacitor element. Thus, the reference is entirely silent about the method of improving such dimple morphology or the technology of forming a thin film on an insulation layer with excellent uniformity in terms of film quality and film thickness.

In a first aspect, the present invention provides a method of forming. a film on a substrate, comprising:

a first step of carrying out first film formation on an insulation layer formed on said substrate by an ALD process; and

a second step of carrying out second film formation in continuation to said first step by a CVD process.

In another aspect, the present invention provides a method of fabricating a semiconductor device having a channel region, comprising the steps of:

forming a gate insulation film on said channel region; and

forming a gate electrode on said gate insulation film, said step of forming said gate electrode comprising:

a first step of carrying out first film formation on said gate insulation film by an ALD process; and

a second step of carrying out second film formation in continuation to said first step by a CVD process.

According to the present invention it becomes possible to provide a film forming method capable of forming a thin film of excellent film quality and uniformity with high productivity. Further, it becomes possible to provide a fabrication process of a semiconductor device capable of fabricating a semiconductor device with excellent device characteristics and high efficiency.

Other objects and further features of the present invention will become apparent from the following detailed description when read in conjunction with the attached drawings.

### BRIEF DESCRIPTION OF THE DRAWINGS

FIG. 1 is a diagram showing a conventional film forming method schematically;

FIG. 2 is a diagram comparing film formation of an ALD process and a CVD process;

FIGS. 3A and 3B are diagrams showing a film forming method according to Embodiment 1 of the present invention;

FIG. 4 is a timing chart showing a gas supply used in the film forming method according to Embodiment 1;

FIG. 5 is a diagram showing an example of a deposition apparatus used in the film forming method of Embodiment 1;

FIGS. 6A-6F are diagrams showing the fabrication process of a semiconductor device according to Embodiment 2;

FIG. 7 is a diagram showing electric properties of the semiconductor device fabricated with the method of Embodiment 2.

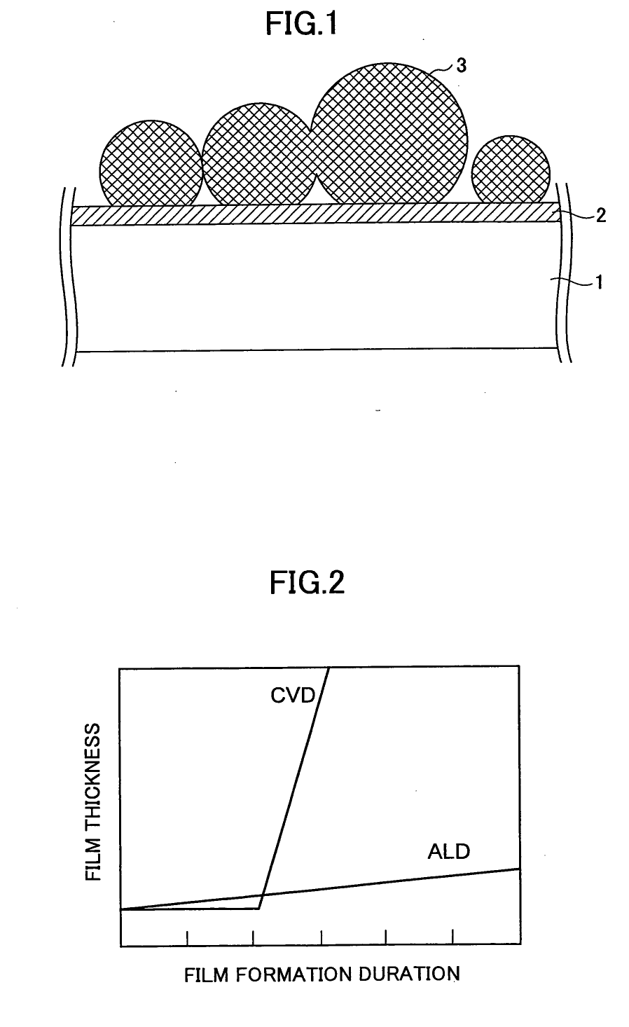

### DETAILED DESCRIPTION OF THE PREFERRED EMBODIMENTS

Next, the present invention will be described for embodiments with reference to the drawings.

### Embodiment 1

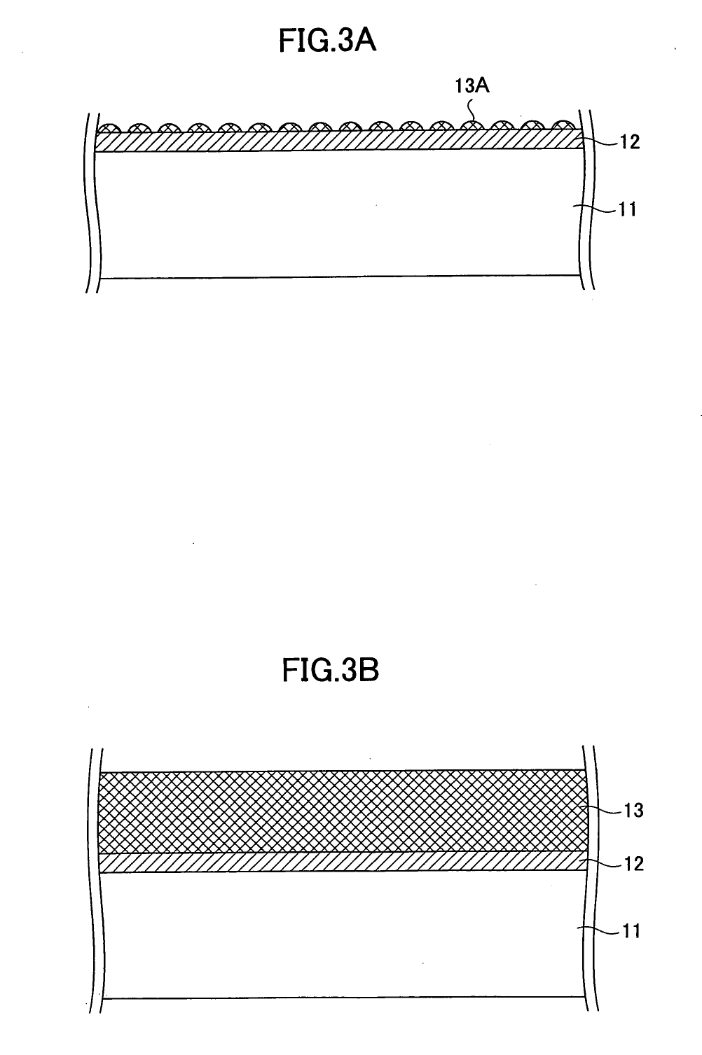

FIGS. 3A-3B are diagrams showing a film forming method according to Embodiment 1 of the present invention schematically step by step, wherein the process of FIGS. 3A-3B constitute a part of the fabrication process of a MOS semiconductor transistor.

Referring to FIG. 3A, there is formed a gate insulation film 12 on a semiconductor substrate 11 of Si, or the like. Typically, the gate insulation film 12 is formed of a SiO₂ film (silicon oxide film), wherein the gate insulation film 12 may also be formed of a so-called high-K dielectric material such as hafnium oxide (HfO₂) or zirconium oxide (ZrO₂) . Further, the gate insulation film 12 may be formed of lamination of an SiO₂ film and HfO₂ film or ZrO₂ film.

On the gate insulation film 12, a gate electrode film of metal is formed according to the process described below.

Thus, with the present embodiment, nuclei 13A of the metal forming the gate electrode are formed on the gate insulation film 12 in a first step by an ALD process.

In the conventional CVD process or MOCVD process, there arises an incubation time in the initial phase of film formation when a metal film is formed on an insulation film as in the present case, and formation of nuclei does not occur immediately. On the other hand, once there is formed a nucleus or nuclei with low density on such an insulation film, there is caused sudden growth in the nucleus or nuclei thus formed, resulting in formation of a metal film characterized by large crystal grains. Thereby, the quality of the metal film is deteriorated inevitably.

Thus, with the present embodiment, the nuclei of the metal of the gate electrode are formed on the gate insulation film with high density by using an ALD process explained below.

Thus, a first reaction gas is supplied to the substrate 11 and hence to the surface of the gate insulation film 12 such that the molecules in the first reaction gas cause chemical adsorption to the gate insulation film 12. Thereafter, the molecules of the first reaction gas not adsorbed to the gate insulation film 12 are removed from the substrate 11.

Next, a second reaction gas that reacts with the first reaction gas is supplied to the substrate 11 and hence to the surface of the gate insulation film 12, wherein the second reaction gas causes reaction with the molecules of the first reaction gas adsorbed to the gate insulation film, and with this, nuclei 13A of the metal forming the gate electrode are formed on the gate insulation film 12. Thereafter, the molecules of the second reaction gas remaining unreacted are removed from the substrate.

Further, by repeating the supply and removal of the first reaction gas and the supply and removal of the second reaction gas plural times, the metal nuclei 13A are formed on the insulation film with high density.

Next, in the second step shown in FIG. 3B, the foregoing first reaction gas and the second reaction gas are supplied to the substrate 11 carrying the insulation film 12 thus formed with the metal nuclei 13A, and there is formed a gate electrode film 13 of the foregoing metal on the gate insulation film 12 by an MOCVD process. Because the gate insulation film 12 is already formed with the metal nuclei 13A with high density in the step of FIG. 3A, growth of the metal film 13 on the gate insulation film 12 occurs immediately upon commencement of the MOCVD process, and it becomes possible to suppress the occurrence of incubation time effectively with the present embodiment. Further, because the growth of the metal film 13 starts from the metal nuclei 13A that are formed on the gate insulation film 12 with high density, the metal film 13 thus formed is characterized by high quality and high uniformity with regard to the film quality and film thickness.

Because of the high deposition rate achieved with the CVD process of FIG. 3B as compared to the ALD process of FIG. 3A, the film forming process of the present embodiment provides a large deposition rate as a whole, and the productivity of semiconductor fabrication is improved.

In the illustrated example, it should be noted that the gate electrode 13 comprises Ru, and the second step of FIG. 3B forms a Ru film as the metal film 13 while using an MOCVD process.

Conventionally, a gate electrode formed on a gate insulation film has been generally formed py using polysilicon.

On the other hand, in the case of using polysilicon for the gate electrode, there arises a problem, associated with miniaturization of design, that control of threshold voltage becomes difficult, and because of this, it becomes difficult to suppress increase of electrode resistance. As a result, there has been caused increase of power consumption. It should be noted that the foregoing problem is particularly deteriorated in the case of using a high-K dielectric film for the gate insulation film. There are a number of reports confirming that the foregoing tendency appears particularly conspicuously in a specific material that contains Hf.

In view of the situation noted before, there is a proposal of using a metal such as Ru for the gate electrode. By using a metal material such as Ru for the gate electrode, it becomes possible to suppress the increase of threshold voltage of the MOS transistor caused when polysilicon gate electrode is provided on a gate insulation film of metal oxide.

Particularly, Ru has an advantageous feature of easiness of processing such as etching as compared with other metals such as Pt. Further, with the use of Ru, it becomes possible to use a common film-forming process developed for other metals such as Ir. Further, in view of the work function having the value of about 5 eV, use of Ru is thought advantageous for forming the gate electrode of MOS transistor, particularly the gate electrode of a p-channel MOS transistor.

In the foregoing example, a metal organic gas is used for the first reaction gas, while a gas containing oxygen and forming a metal upon reaction with the first process gas such as O₂ (oxygen) and O₃ (ozone), H₂O, and the like, is used for the second reaction gas. In this case, the first reaction gas is called also as “precursor”.

In the case of forming Ru, it is possible to use Ru(EtCp)₂, for example, for the metal organic reaction gas, wherein it should be noted that Ru(EtCp)₂ has an advantageous feature in that particle formation at the time of Ru film formation is small as compared with other metal organic gas that contains Ru. Further, Ru(EtCp)₂ has advantageous features of easiness in handling over other precursors in that it can be purified in short time, taking a liquid state at room temperature, and providing high vapor pressure at the temperature near 100° C.

Thus, it is possible to form a Ru film stably and with reproducibility by using Ru(EtCP)₂ for the first reaction gas and O₂ for the second reaction gas. Further, it is possible to use the same reaction gas for the first step and the second step. Further, it is possible to use the same first reaction gas and the second reaction gas used with the first step (ALD film forming process) also in the second step (CVD film forming process). With this, it becomes possible to simplify the gas supply method and system.

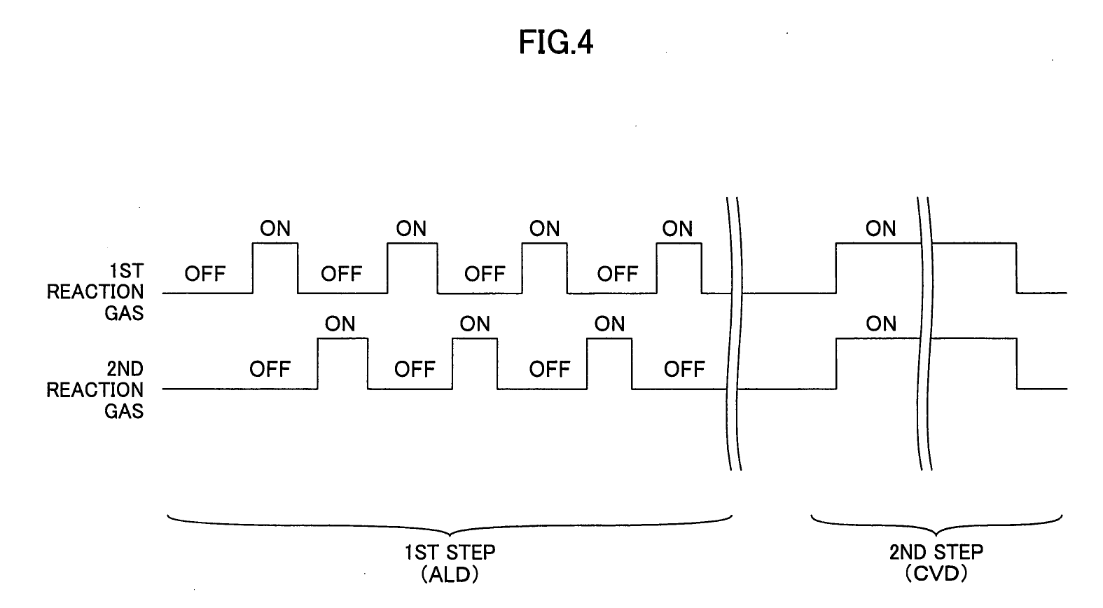

FIG. 4 shows the timing chart showing the timing of supplying the first reaction gas and the second reaction gas to the substrate schematically with the film forming process of the present embodiment.

Referring to FIG. 4, the first step (ALD step) corresponds to the step of FIG. 3A, while the second step (CVD step) corresponds to the step of FIG. 3B.

In the first step, the first reaction gas is supplied for example to the substrate to be processed for a predetermined duration (shown in the drawing by ON), and the supply of the first reaction gas is stopped thereafter (shown in the drawing by OFF). After the supply of the first reaction gas is stopped, the first reaction gas remaining on the substrate unreacted is removed therefrom.

Next, the second reaction gas is supplied to the substrate to be processed for a predetermined duration (shown in the drawing by ON), wherein the supply of the reaction gas is stopped thereafter (shown in the drawing by OFF). After the supply of the second reaction gas is stopped, the second reaction gas remaining on the substrate unreacted is removed therefrom together with reaction byproducts.

Further, the foregoing processes of supplying the first reaction gas and stopping the supply thereof including removal of the first reaction gas and the foregoing process of supplying the second reaction gas and stopping the supply thereof including removal of the second reaction gas, are repeated plural times. With this, nucleation process corresponding to the first film forming step is conducted.

Further, removal of the first reaction gas or second reaction gas from the substrate to be processed is achieved by evacuating a processing vessel of a film forming apparatus (described later) by way of evacuation means such as a vacuum pump.

Further, removal of the first reaction gas from the substrate (removal from the processing vessel) may be conducted simultaneously to the supply of the second reaction gas. Thus, it is possible to carry out the stopping of the first reaction gas and start of supplying the second reaction gas may be conducted simultaneously. Further, in order to reduce the duration of film formation, it is possible to start the supply of the second reaction gas in advance of stopping the supply of the first reaction gas. In this case, the ON timing and the OFF timing overlap to some extent.

On the other hand, in the case the duration in which the first reaction gas and the second reaction gas are supplied simultaneously is too long in such an ALD process, there is caused excessive growth in the metal nuclei (excessive crystal grain size) such as 50 nm or more, and there is a concern that the quality of the film formed in the second step may be deteriorated. Thus, it is preferable to control the duration in which the first reaction gas and the second reaction gas are supplied simultaneously to be smaller than a predetermined duration.

In the second step, film formation is conducted by a CVD process by supplying the first reaction gas and the second reaction gas simultaneously to the substrate held in the processing vessel for substrate processing over a predetermined duration. Further, it would be obvious in the second step that there is no need of start or step supplying the first reaction gas and the second reaction gas simultaneously.

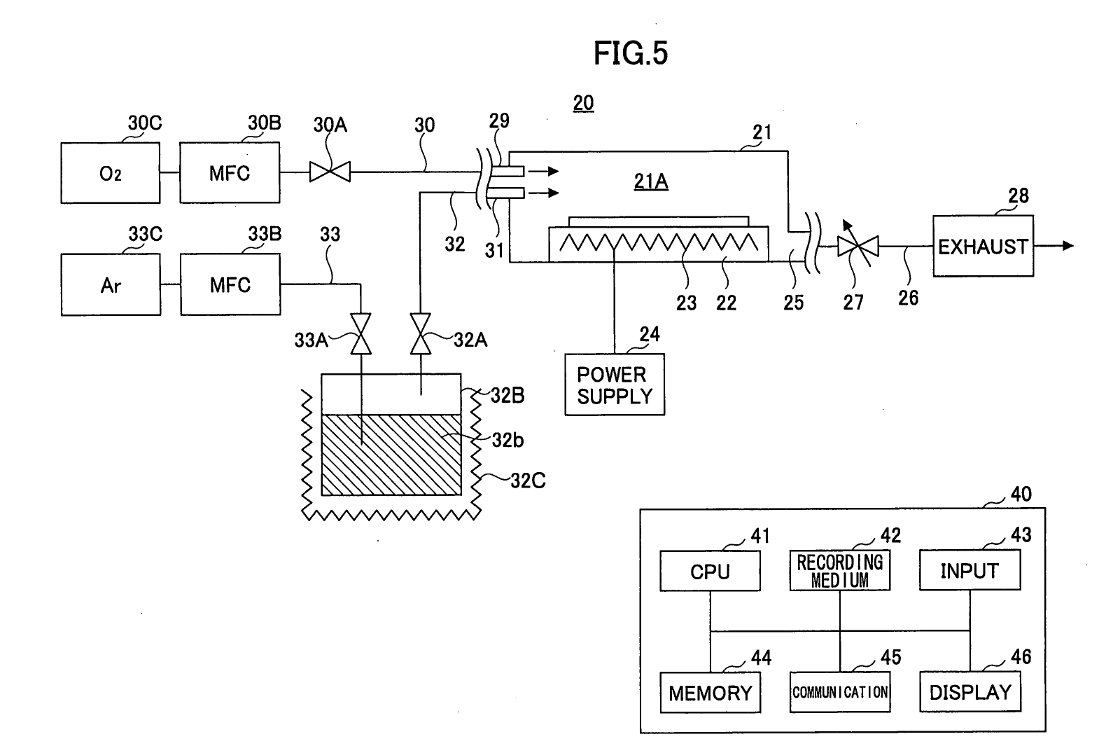

Next, the construction of an exemplary film forming apparatus used with the present invention for carrying out the foregoing film forming process will be explained with reference to FIG. 5.

Referring to FIG. 5, the film forming apparatus 20 of the present embodiment has a processing vessel 21 defining therein an internal space 21A, and a stage 22 is accommodated in the internal space 21A for holding thereon a substrate W to be processed.

Further, heating means 23 such as a heater is embedded in the stage 22 in connection to a power supply unit 24, and with this, it becomes possible to heat the substrate W to a predetermined temperature.

Further, the processing vessel 21 is provided with an evacuation port 25 and an evacuation line 26 is connected to the evacuation port 25, wherein the evacuation line 26 includes evacuation means 28 such as a vacuum pump and pressure regulating means 27 such as a conductance valve. The internal space 21A is evacuated from the evacuation line 26, and with this, the internal space 21A is held at a depressurized state.

Further, gas supply ports 29 and 31 are provided to the processing vessel 21 such that the first reaction gas and the second reaction gas are supplied to the internal space 21A via the gas supply port 31 and the gas supply port 29, respectively. Thereby, it should be noted that the gas supply port 29 is connected with a gas line 30 that includes a valve 30A, a mass flow controller (MFC) 30B and a second reaction gas supply source 30C. Thus, by opening the valve 30A, the second reaction gas such as oxygen (O₂) is supplied to the internal space 21A with a flow rate under control of the MFC 30B.

Further, the gas supply port 31 is connected with a gas line 32 including a valve 32A and a source vessel 32B. The source vessel 32B holds a metal organic source 32b such as Ru(EtCP)₂, and the source material 32b is heated by a heater 32c provided around the source vessel 32B.

The source vessel 32B is connected with a gas line 33 provided with a valve 33A, MFC 33B and a carrier gas source 33C, and a carrier gas such as an Ar gas is supplied to the source vessel 32B from the gas line 33. Thereby, there is caused vaporization of the source material 32b in the source vessel 32B by the heating means 32c, resulting in formation of the first reaction gas. The first reaction gas thus formed is then supplied to the internal space 21A together with the carrier gas supplied to the source vessel 32B. Thus, by opening the valves 32A and 33A, the first reaction gas is supplied to the internal space 21A together with the carrier gas.

With the foregoing film forming apparatus 20, the operation related to film formation such as open/close operation of the valves30A, 32A and 33A, flow rate control by way of the MFCs 30B and 33B, control of the stage 22, control the pressure regulation means 27, vacuum evacuation by the evacuation means 28, are controlled by a program called recipe. Thus, in the system of FIG. 5, the foregoing operations are controlled by a controller 40 that includes a CPU 41. In FIG. 5, illustration of such interconnection is omitted.

The controller 40 includes, in addition to the CPU 41, a recording medium 42 that records the foregoing program, an input part 43 such as a keyboard, a display part 46, a communication pert 45 for connection to the network, and a memory 44.

Next, an example of implementing the film forming method explained with reference to FIGS. 3A, 3B and 4 will be described for the case of using the film forming apparatus 40. In the example hereinafter, a Ru film is formed on a gate insulation film formed on a substrate while using Ru(EtCP)₂ for the source 32b (first reaction gas) and O₂ for the second reaction gas.

First, in the step of FIG. 3A (corresponding to first step of FIG. 4), the valves 32A and 33A are opened, and Ru(EtCP)₂ is introduced to the internal space 21A on the substrate to be processed as the vaporized source material 32b together with Ar. Thereby, there is caused chemical adsorption of Ru(EtCP)₂ thus introduced on the surface of the gate insulation film 12. For example, the Ru(EtCP)₂ source material 32b is supplied with a flow rate of 20-300 sccm together with the Ar gas of the flow rate set to 100-300 sccm under the pressure of 0.5-20 Pa for the internal space 21A, while setting the temperature of the stage 22 to 270-320° C. After supplying the Ru(EtCP)₂ source material 32b for a predetermined duration, the valves 32A and 32B are closed and the supply of the Ru(EtCp)₂ is stopped.

Thereafter, the Ru(EtCP)₂ source material 32b remaining unadsorbed in the internal space 21A is evacuated from the evacuation port 25 to the outside of the internal space 21A.

Next, the valve 30A is opened and the oxygen gas (O₂) is introduced into the internal space 21A and to the surface of the substrate to be processed. The oxygen gas O₂ thus supplied cause reaction with the Ru(EtCp)₂ adsorbed to the insulation film 12, and there is formed a Ru film (Ru nuclei) 13A on the gate insulation film 12 primarily as a result of reaction of the oxygen gas with carbon or hydrogen contained in the Ru(EtCp)2 source material 32b. In this case, the flow rate of the oxygen gas is set to 10-100 sccm and the reaction is caused at the substrate temperature (temperature of the stage 22) of 270-320° C. under the pressure of the internal space 21A of 0.5-20 Pa. After supplying the oxygen gas for a predetermined duration, the valve 30A is closed and the supply of the oxygen gas is stopped.

Thereafter, unreacted oxygen gas or reaction byproducts are removed from the substrate 11 to the outside of the internal space 21A from the evacuation port 25.

Thereafter, supply and removal of the Ru(EtCp)₂ source material 32b including stopping the supply of the Ru(EtCp)₂ source material 32b are repeated, and with this, the first film forming step (nucleation step) is conducted. Defining the interval from the supply of the Ru(EtCp)₂ source material to the end of supplying the oxygen gas including removal thereof as one cycle, it is possible to form the Ru film (Ru nuclei) 13A on the gate insulation film 12 with a thickness or nucleus size of 5-20 nm.

Next, in the step of FIG. 3B (second step of FIG. 4), the Ru(EtCp)₂ source material 32b and the oxygen gas (O₂) are supplied simultaneously to the foregoing internal space 21A by opening the valves 30A, 32A and 33A, and film formation according to a CVD process is conducted. Thereby, because there are already formed the nuclei 13A of Ru on the gate insulation film 12 with high density in the first step, there occurs a growth of nuclei immediately with the step of FIG. 3B from the nuclei 13A. Thereby, the gate electrode film 13 of Ru is formed with excellent film quality and with excellent uniformity with regard to film quality and film thickness.

In the step of FIG. 3B, the Ru(EtCp)₂ source material 32b may be supplied with the flow rate of 20-300 sccm, the Ar gas may be supplied with the flow rate of 100-300 sccm, the oxygen gas may be supplied with the flow rate of 100-500 sccm, and the film formation process may be conducted at the substrate temperature (temperature of the stage 21) of 270-350° C. under the pressure inside the internal space 21A of 0.5-20 Pa.

By conducting the foregoing first and second steps, it is possible to form the gate electrode of excellent film quality and excellent uniformity in terms of film quality and uniformity, with the thickness of about 10-50 nm.

### Embodiment 2

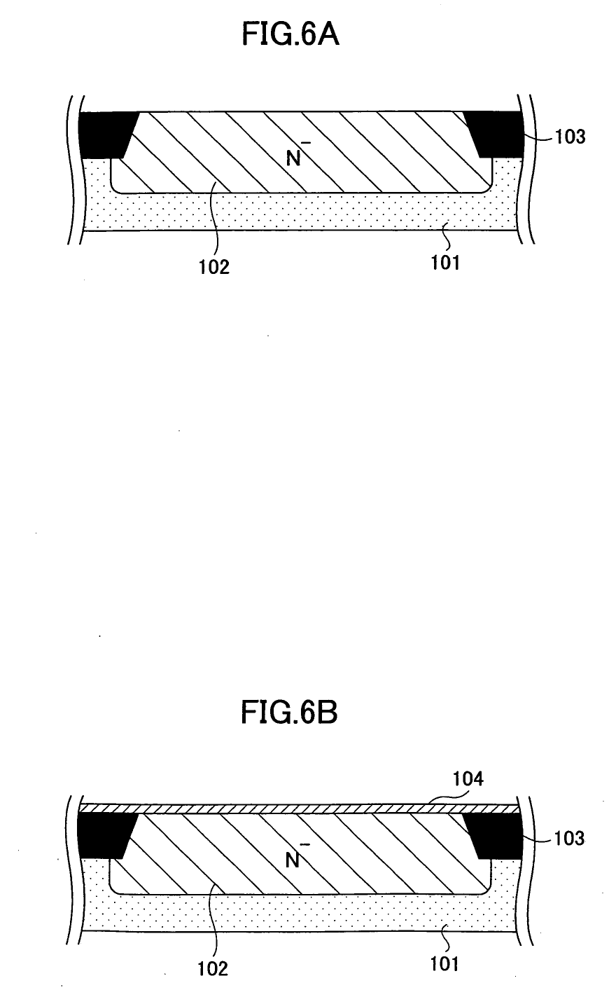

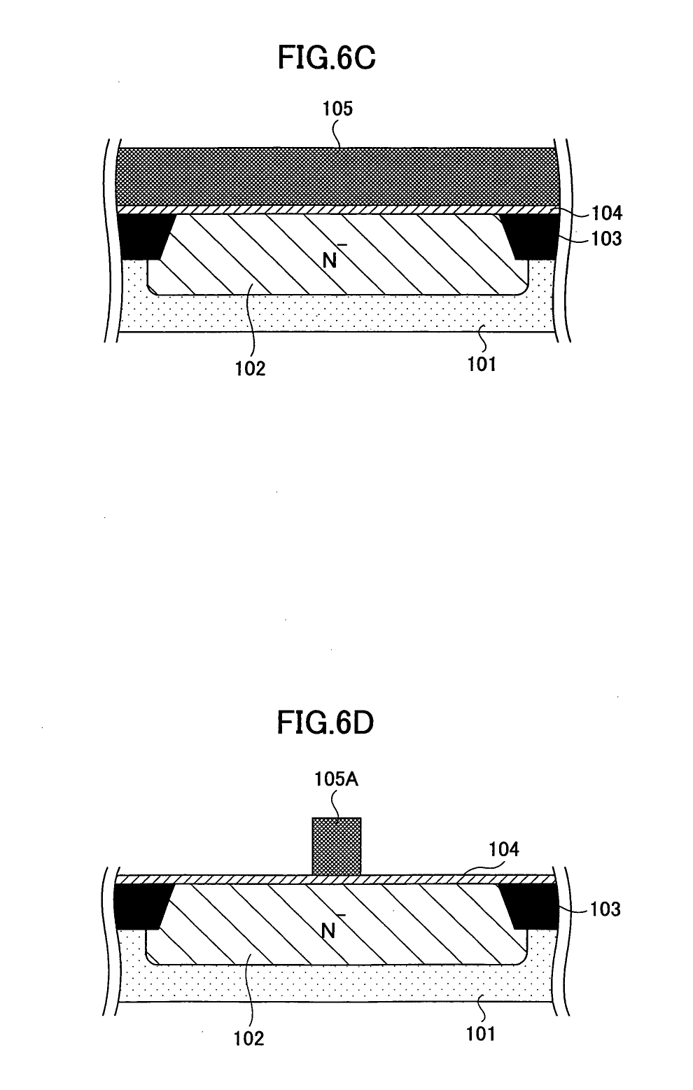

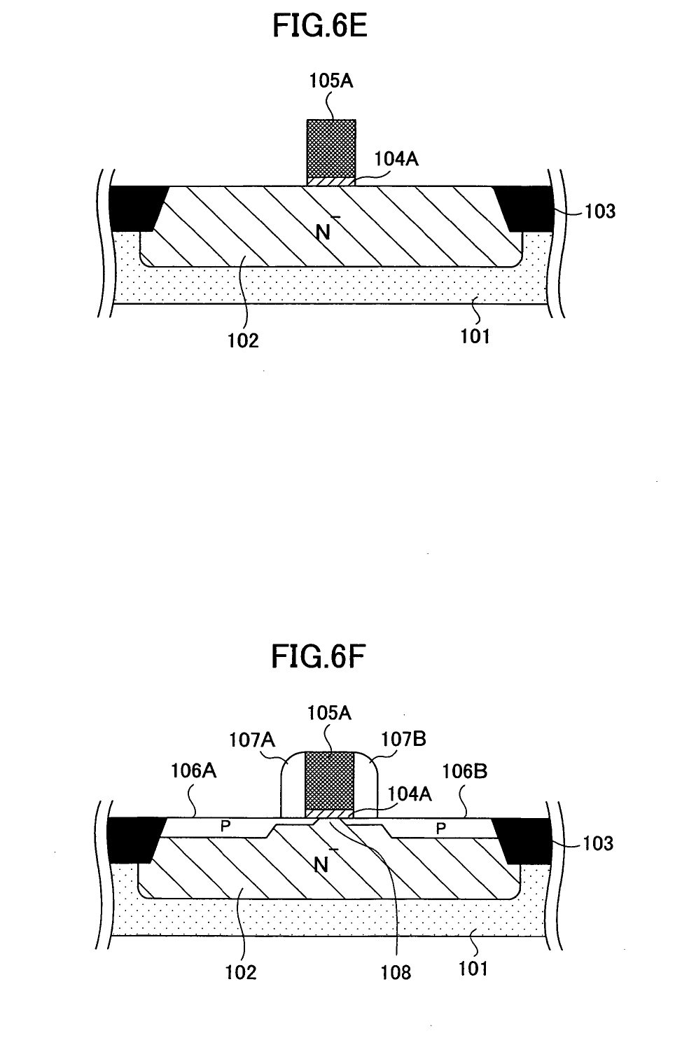

Next, the method of fabricating a semiconductor device according to Embodiment 2 of the present invention that includes the foregoing film forming process will be described step by step with reference to FIGS. 6A-6F.

First in the step of FIG. 6A, there is formed a device region 102 on a silicon substrate 101 by forming a device isolation region 103 of STI structure. Further, an impurity element of n-type is introduced to the device region by an ion implantation process and there is formed an n-type diffusion region in correspondence to the foregoing device region 102.

Next, in the step of FIG. 6B, a high-K gate insulation film 104 of metal oxide such as HfO₂ is formed on the device region 102 by an ALD process or MOCVD process with a thickness of 3-5 nm. In this case, the gate insulation film 104 may be formed in the lamination of an SiO₂ film and an HfO₂ film. Further, it is possible to add nitrogen to such a gate insulation film 104 or to include a nitride film further to the gate insulation film 104 according to the needs.

Next, in the step of FIG. 6C, a gate electrode film 105 of Ru is formed on the gate insulation film 104 with a thickness of 25-50 nm according to the process explained with reference to FIGS. 3A and 3B and FIG. 4. Here, it should be noted that the substrate 101, the gate insulation film 104 and the gate electrode film 105 correspond respectively the substrate 11, the gate insulation film 12 and the gate electrode 13. By using the film forming process explained already, it is possible to form the Ru gate electrode film 105 to have excellent film quality and excellent uniformity with regard to film quality and film thickness, while maintaining efficient film forming rate.

Next, in the step of FIG. 6D, the Ru gate electrode film 105 is subjected to a patterning process while using lithography and dry etching, and with this, a Ru gate electrode pattern 105A is formed from the Ru gate electrode film 105 with desired gate length and gate width.

Next, in the step of FIG. 6E, the part of the gate insulation film 104 exposed as a result of patterning of the gate electrode pattern 105A is subjected to an etching process, and with this, the gate insulation film 104 is patterned to form a gate insulation film pattern 104A.

Next, in the step of FIG. 6F, a p-type impurity element is introduced into the exposed device region 102 by an ion implantation process while using the gate electrode pattern 105A as a mask. Further, an ion implantation process is conducted again after forming sidewall insulation films 107A and 107B on the respective sidewall surfaces of the gate electrode 105A, while using the gate electrode pattern 105A and the sidewall insulation films 107A and 107B as a mask, and with this, there are formed source and drain regions 106A and 106B of p-type in the device region 102 at respective outer sides of the sidewall insulation film 107A and the sidewall insulation film 107B.

With this, there is formed a channel region 108 in the device region 102 right underneath the gate insulation film pattern 104A between the source region 106A and the drain region 106B. The semiconductor device thus formed forms an n-channel MOS transistor.

Further, it is possible to form an interlayer insulation film or multilayer interconnection structure including stack of interconnection layers connected and contact plugs in the process thereafter according to the needs.

Further, with the fabrication process of the semiconductor device of the present embodiment, it is possible to use the film forming method of Example 1 also for the formation of the gate insulation film 104.

For example, it is possible to form the gate insulation film 104 by an HfO₂ film similarly to the case of forming the Ru gate electrode film by using the process explained in Embodiment 1 with reference to FIGS. 3A, 3B and 4, except that TDMAH (Tetrakis DiMethyl Amino Hafnium, Hf[N(CH₃)₂]₄) is used for the firs reaction gas and H₂O is used for the second reaction gas.

By doing so, a high film formation rate is maintained in the case of forming the gate insulation film 104 of HfO₂ while maintaining excellent film quality and excellent film uniformity with regard to the film quality and film thickness. Further, it becomes possible to form the gate insulation film 104 and the gate electrode film 105 continuously while using the same apparatus such as the one shown in FIG. 5, for example, and thus in the internal space 21A of the processing vessel 21. With this, productivity of fabricating the semiconductor device is improved.

It should be noted that the first gas and the second gas noted before are merely presented for the exemplary purposes, and it is also possible to use other various gases. Further, the film forming method of Example 1 is by no means limited to the formation of gate electrode or gate insulation film, but is applicable to the formation of other various devices.

### EXAMPLE 3

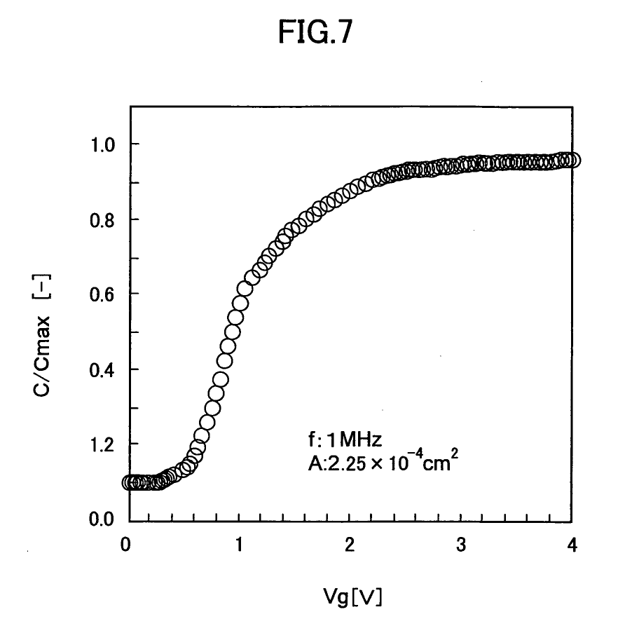

FIG. 7 shows the result of investigation made on the characteristics of the device formed according to the process similar to the one explained in Example 2. More specifically, FIG. 7 shows the electric characteristics (C-V characteristics) observed for a laminated structure of (Ru(50 nm)/HfO₂(4.8 nm) /SiO₂(8 nm)/n-Si).

Referring to FIG. 7, it can be seen that excellent C-V characteristics is attained with the foregoing structure, and it was confirmed that the MOS transistor formed with the foregoing process performs excellently.

According to the present invention it becomes possible to provide a film forming method capable of forming a thin film of excellent film quality and uniformity with high productivity. Further, it becomes possible to provide a fabrication process of a semiconductor device capable of fabricating a semiconductor device of excellent device characteristics with high productivity.

Further, the present invention is not limited to the embodiments described heretofore, but various variations and modifications may be made without departing from the scope of the invention.

What is claimed is:

1. A method of forming a film on a substrate, comprising:
a first step of carrying out first film formation on an insulation layer formed on said substrate by an ALD process; and
a second step of carrying out second film formation in continuation to said first step by a CVD process.

2. The method as claimed in claim 1, wherein said film formed on said insulation layer comprises a conductive film containing a metal.

3. The method as claimed in claim 2, wherein said metal comprises Ru.

4. The method as claimed in claim 2, wherein said conductive film forms a gate electrode of a MOS transistor.

5. The method as claimed in claim 1, wherein a first reaction gas of a metal organic source gas and a second reaction gas reactive with said first reaction gas are supplied to said substrate in said first and second steps.

6. The method as claimed in claim 5, wherein said first reaction gas comprises Ru(EtCp)₂.

7. The method as claimed in claim 6, wherein said second reaction gas comprises an O₂ gas.

8. A method of fabricating a semiconductor device having a channel region, comprising the steps of:
forming a gate insulation film on said channel region; and
forming a gate electrode on said gate insulation film, said step of forming said gate electrode comprising:
a first step of carrying out first film formation on said gate insulation film by an ALD process; and
a second step of carrying out second film formation in continuation to said first step by a CVD process.

9. The method as claimed in claim 8, wherein said gate electrode comprises Ru.

10. The method as claimed in claim 8, wherein said first reaction gas of a metal organic source gas and a second reaction gas reactive to said first reaction gas are supplied to the gate insulation film in said first and second steps.

11. The method as claimed in claim 10, wherein said first reaction gas comprises Ru(EtCp)₂.

12. The method as claimed in claim 11, wherein said second reaction gas comprises an O₂ gas
